(19) United States
(12) Patent Application Publication
(10) Pub. No.: US 2016/0244471 A1
(43) Pub. Date: Aug. 25, 2016

(54) PHENOXYCYCLOTRIPHOSPHAZENE ACTIVE ESTER, HALOGEN-FREE RESIN COMPOSITION AND USES THEREOF

(71) Applicant: Shengyi Technology Co., Ltd., Dongguan City, Guangdong (CN)

(72) Inventor: Yueshan HE, Dongguan City (CN)

(21) Appl. No.: 15/027,369

(22) PCT Filed: Jun. 13, 2014
(86) PCT No.: PCT/CN2014/079854

§ 371 Date: Apr. 5, 2016

(51) Int. Cl. C07F 9/6581; C08L 79/02; C08L 75/00; H05K 1/03; C08L 63/08; C08J 5/24; C08J 5/04; C09K 21/14; C08G 59/30; C08L 71/00

(52) U.S. Cl. CPC C07F 9/65812; C08G 59/304; C08L 79/02; C08L 75/00; C08L 71/00; C08L 63/08; C08J 5/24; C08J 5/043; C09K 21/14; H05K 1/0373; C08L 2201/02; C08L 2201/22; C08L 2205/03; C08J 2363/08; C08J 2379/02; C08J 2463/08; C08J 2435/06; C08J 2375/00; C08J 2371/00; C08L 2203/20; H05K 2201/012; H05K 2201/0145

(57) ABSTRACT

The present invention discloses a phenoxycyclotriphosphazene active ester, a halogen-free resin composition and uses thereof. The phenoxycyclotriphosphazene active ester comprises at least 65 mol. % of a substance having the following structural formula. The halogen-free resin composition comprises 5-50 parts by weight of a phenoxycyclotriphosphazene active ester, 15-85 parts by weight of a thermosetting resin, 1-35 parts by weight of a curing agent, 0-5 parts by weight of a curing accelerator and 0-100 parts by weight of an inorganic filler. The present invention discloses introducing phenoxycyclotriphosphazene active ester into a thermosetting resin, reacting active esters with thermosetting resins, such as epoxy resin, without producing hydroxy groups, which not only satisfies the requirements on being halogen-free and flame retardancy, but also improves the electrical properties (decreasing and stabilizing Dk and Df) of the system, so as to make non-halogenation of high frequency and high speed substrate materials possible.

### BRIEF SUMMARY OF THE INVENTION

The present invention relates to a phenoxycyclotriphosphazene active ester, a halogen-free resin composition and uses thereof, wherein said halogen-free resin composition is used for preparing prepregs, laminates, and printed wiring boards.

### BACKGROUND OF THE INVENTION

In recent years, electronic equipment, especially those using broadband, e.g., mobile communication devices, have been continuously improved with the development of integrated technology, bonding technology and assembly technology of semiconductor devices used in electronic equipment, high-density electronic device components and the wiring of high-density printed wiring boards.

Printed wiring boards, as a component of such electronic devices, are developed in the direction of higher-integration printed wiring boards and more precise wiring. In order to increase the signal transmission rate to a level required for speeding up information processing, the effective method is to decrease the dielectric constant of the materials used therein; in order to decrease the transmission loss, the effective method is to use materials having a lower dielectric loss tangent (dielectric loss).

With the rapid development of electronic technique, environmental protection is more and more pursued. The conventional high-frequency and high-speed materials primarily achieve the objective of flame retardancy by using halides and antimonides. While igniting and combusting, copper clad laminates containing halides not only produce a large amount of smoke and unpleasant odor, but thy also give off halogen hydride gas having a high toxicity and a strong corrosivity, which pollutes the environment and does harm to human health. Currently, epoxy resins corresponding to phosphorous-containing phenanthrene compounds DOPO or ODOPB are used in industry to make common FR-4 achieve flame retardancy. However, phosphorous-containing phenanthrene compounds DOPO or ODOPB still have a high water absorption rate, which has an extremely great effect on the dielectric constant and dielectric loss angle tangent of high-frequency and high-speed materials.

### DETAILED DESCRIPTION OF THE INVENTION

As for the existing technical problems, one objective of the present invention lies in providing a phenoxycyclotriphosphazene active ester, introducing it into a thermosetting resin, reacting its reactive groups with a specific thermosetting resin without producing hydroxyl groups, which can not only satisfy the requirements of being halogen-free and flame retardancy, but also can make a few changes to the dielectric constant and dielectric loss angle tangent, so as to improve the electrical properties and make being halogen-free of high-frequency and high speed substrate materials possible.

In order to achieve the aforesaid objective, the present invention uses the following technical solution:

a phenoxycyclotriphosphazene active ester, characterized in comprising at least 65 mol. % of a substance having the following structural formula:

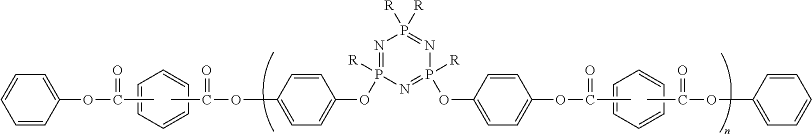

wherein,

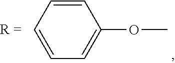

n represents any number between 0.25 and 3.

Said at least 65% is selected from the group consisting of, e.g., 66%, 67%, 68%, 69%, 70%, 71%, 72%, 73%, 74%, 75%, 76%, 77%, 78%, 79%, 80%, 81%, 82%, 83%, 84%, 85%, 86%, 87%, 88%, 89%, 90%, 91%, 92%, 93%, 94%, 95%, 96%, 97%, 98% or 99%.

n is selected from the group consisting of, e.g., 0.28, 0.35, 0.42, 0.5, 0.6, 0.7, 0.8, 0.9, 1, 1.1, 1.2, 1.3, 1.4, 1.5, 1.6, 1.7, 1.8, 1.9, 2, 2.1, 2.2, 2.3, 2.4, 2.5, 2.6, 2.7, 2.8 or 2.9.

The exemplary method for preparing phenoxycyclotriphosphazene active ester is stated as follows:

A solvent, a phenoxycyclotriphosphazene containing hydroxyl groups (wherein those containing two hydroxyl groups are in a proportion of higher than 65%), an acid-binding agent and a catalyst were added into a reaction device, stirred, protected by introducing nitrogen, and gradually dripped at a temperature of less than 20° C. with a certain amount of p-benzoyl chloride. After reacting for 1-8 hours, an excess of phenol was added, further reacted for 1-8 hours, cooled to room temperature, and filtered by suction. The filtrate was pressure-distilled to evaporate the solvent to obtain a viscous product, i.e., phenoxycyclotriphosphazene active ester.

The phenoxycyclotriphosphazene active ester prepared by such method is a mixture, and inevitably contains other components, e.g., impurities, wherein there contains at least 65% of the substance having the aforesaid structural formula.

The second objective of the present invention lies in providing a halogen-free resin composition, comprising 5-50 parts by weight of a phenoxycyclotriphosphazene active ester, 15-85 parts by weight of a thermosetting resin, 1-35 parts by weight of a curing agent, and 0-5 parts by weight of a curing accelerator and 0-100 parts by weight of an inorganic filler,

wherein the thermosetting resin is selected from the group consisting of epoxy resin, benzoxazine resin, cyanate resin, bismaleimide resin, reactive polyphenyl ether resin or hydrocarbon resin, or a mixture of at least two or more thereof.

The reactive polyphenyl ether resin is a polyphenyl ether resin in which crosslinking reactive groups are introduced into the main chain thereof.

Said phenoxycyclotriphosphazene active ester is in an amount of, e.g., 7, 9, 11, 13, 15, 17, 19, 21, 23, 25, 27, 29, 31, 35, 37, 39, 41, 43, 45, 47 or 49 parts by weight.

Said thermosetting resin is in an amount of, e.g., 18, 21, 24, 27, 30, 33, 36, 39, 42, 45, 48, 51, 54, 57, 60, 63, 66, 69, 72, 75, 78, 81 or 84 parts by weight.

Said curing agent is in an amount of, e.g., 2, 4, 6, 8, 10, 12, 14, 16, 18, 20, 22, 24, 26, 28, 30, 32 or 34 parts by weight.

Said curing accelerator is in an amount of, e.g., 0.2, 0.5, 0.8, 1.1, 1.4, 1.7, 2, 2.3, 2.6, 2.9, 3.2, 3.5, 3.8, 4.1, 4.4, 4.6 or 4.8 parts by weight.

Said inorganic filer is in an amount of, e.g., 4, 8, 12, 16, 20, 24, 28, 32, 36, 40, 44, 48, 52, 56, 60, 64, 68, 72, 76, 80, 84, 88, 92, 96 or 98 parts by weight, preferably 25-100 parts by weight.

The present invention discloses introducing a phenoxycyclotriphosphazene active ester into a thermosetting resin, reacting the active esters with epoxy resin without producing hydroxyl groups, which not only can satisfy the requirements of being halogen-free and flame retardancy, but also can improve the electrical properties of the system (decreasing and stabilizing Dk and Df), so as to make being halogen-free of high-frequency and high speed substrate materials possible.

Preferably, the thermosetting resin comprises dicyclopentadiene, biphenyl or naphthalene ring. Due to dicyclopentadiene, biphenyl or naphthalene ring group, the dielectric properties thereof are superior to the thermosetting resins having other structures.

Preferably, the epoxy resin is anyone selected from the group consisting of bisphenol A epoxy resin, bisphenol F epoxy resin, DCPD epoxy resin, triphenol epoxy resin, biphenyl epoxy resin or naphthol epoxy resin, or a mixture of at least two or more thereof. The mixture is selected from the group consisting of: e.g., a mixture of bisphenol A epoxy resin and bisphenol F epoxy resin, a mixture of DCPD epoxy resin and triphenol epoxy resin, a mixture of biphenyl epoxy resin and naphthol epoxy resin, a mixture of bisphenol A epoxy resin, bisphenol F epoxy resin and DCPD epoxy resin, and a mixture of triphenol epoxy resin, biphenyl epoxy resin and naphthol epoxy resin.

Preferably, the epoxy resin is a phosphorous-containing epoxy resin containing phosphorous in an amount of 1.5-6.0 wt. % (e.g., 1.8 wt. %, 2.1 wt. %, 2.4 wt. %, 2.7 wt. %, 3 wt. %, 3.3 wt. %, 3.6 wt. %, 3.9 wt. %, 4.2 wt. %, 4.5 wt. %, 4.8 wt. %, 5.1 wt. %, 5.4 wt. % or 5.7 wt. %).

Preferably, the benzoxazine resin is any resin selected from the group consisting of bisphenol A benzoxazine resin, bisphenol F benzoxazine resin, DCPD benzoxazine resin or phenothalin benzoxazine resin, or a mixture of at least two or more thereof. The mixture is selected from the group consisting of, e.g., a mixture of bisphenol A benzoxazine resin and bisphenol F benzoxazine resin, a mixture of DCPD benzoxazine resin and phenothalin benzoxazine resin, a mixture of bisphenol A benzoxazine resin, bisphenol F benzoxazine resin and DCPD benzoxazine resin, a mixture of phenothalin benzoxazine resin, bisphenol A benzoxazine resin, bisphenol F benzoxazine resin, DCPD benzoxazine resin, and phenothalin benzoxazine resin.

Preferably, the cyanate resin is any resin selected from the group consisting of bisphenol A cyanate resin, DCPD cyanate resin and phenolic aldehyde cyanate resin, or a mixture of at least two or more thereof. The mixture is selected from the group consisting of, e.g., a mixture of bisphenol A cyanate resin and DCPD cyanate resin, a mixture of phenolic aldehyde cyanate resin and bisphenol A cyanate resin, a mixture of DCPD cyanate resin and phenolic aldehyde cyanate resin, and a mixture of bisphenol A cyanate resin, DCPD cyanate resin, and phenolic aldehyde cyanate resin.

Preferably, the bismaleimide resin comprises 4,4′-diphenylmethane bismaleimide and/or allyl-modified diphenylmethane bismaleimide.

Preferably, the reactive polyphenyl ether resin has a average molecular weight of 1000-7000, and has the reactive groups of hydroxyl groups and/or double bonds.

Preferably, the hydrocarbon resin is any resin selected from the group consisting of: vinyl styrene butadiene resin having a average molecular weight of less than 11,000, vinyl polybutadiene resin having polar groups and maleic anhydride-grafted butadiene and styrene resin, or a copolymer of at least two or more thereof.

Preferably, the curing agent is any material selected from the group consisting of dicyandiamide, aromatic amine, anhydride, phenolic compounds, triene isocyanurate and phosphorous-containing phenolic aldehyde, or a mixture of at least two or more thereof. The mixture is selected from the group consisting of, e.g., a mixture of dicyandiamide and aromatic amine, a mixture of anhydride and phenolic compounds, a mixture of triene isocyanurate and phosphorous-containing phenolic aldehyde, a mixture of dicyandiamide, aromatic amine and anhydride, and a mixture of phenolic compounds, triene isocyanurate, and phosphorous-containing phenolic aldehyde.

Preferably, the curing accelerator is anyone selected from the group consisting of 2-methylimidazole, 2-ethyl-4-methylimidazole, 2-phenylimidazole, pyridine, DMP-30, hexamethylenetetramine, dicumyl peroxide, t-butyl peroxybenzoate, 2,5-di(2-ethylhexanoylperoxy)-2,5-dimethylhexane, acetylacetonate and zincate, or a mixture of at least two or more thereof. The mixture is selected from the group consisting of, e.g., a mixture of 2-methylimidazole and 2-ethyl-4-methylimidazole, a mixture of 2-phenylimidazole and pyridine, a mixture of DMP-30 and hexamethylenetetramine, a mixture of dicumyl peroxide and t-butyl peroxybenzoate, a mixture of 2,5-di(2-ethylhexanoylperoxy)-2,5-dimethylhexane, acetylacetonate and zincate, a mixture of 2-methylimidazole, 2-ethyl-4-methylimidazole and 2-phenylimidazole, a mixture of pyridine, DMP-30 and hexamethylenetetramine, and a mixture of dicumyl peroxide, t-butyl peroxybenzoate, 2,5-di(2-ethylhexanoylperoxy)-2,5-dimethylhexane, acetylacetonate, and zincate.

Preferably, the inorganic filler is any material selected from the group consisting of aluminum hydroxide, magnesium hydroxide, zeolite, wollastonite, silica, magnesium oxide, calcium silicate, calcium carbonate, clay, talc, mica, or a mixture of at least two or more thereof. The mixture is selected from the group consisting of, e.g., a mixture of aluminum hydroxide and magnesium hydroxide, a mixture of zeolite and wollastonite, a mixture of silica and magnesium oxide, a mixture of calcium silicate and calcium carbonate, a mixture of clay, talc and mica, a mixture of aluminum hydroxide, magnesium hydroxide and zeolite, a mixture of wollastonite, silica, magnesium oxide and calcium silicate, and a mixture of calcium carbonate, clay, talc, and mica.

The wording “comprise(s)/comprising” in the present invention means that, besides said components, there may be other components which endow the halogen-free resin composition with different properties. In addition, the wording “comprise(s)/comprising” in the present invention may be replaced with “is/are” or “consist of” in a closed manner.

Said halogen-free resin composition may contain various additives, e.g., antioxidants, heat stabilizers, antistatic agents, ultraviolet absorbers, pigments, colorants or lubricants, which may be used alone or in combination.

The third objective of the present invention is to provide a prepreg comprising a reinforcing material and the aforesaid halogen-free resin composition attached thereon after impregnation and drying.

The fourth objective of the present invention is to provide a laminate, comprising at least one prepreg as stated above.

The fifth objective of the present invention is to provide a printed wiring board, comprising at least one prepreg as stated above.

The exemplary method for preparing the laminate comprises the following steps:

(1) dissolving a formula amount of the phenoxycyclotriphosphazene active ester in a solvent such as benzene or ketone, etc., completely dissolving at room temperature or a medium temperature;
(2) adding a formula amount of a thermosetting resin, a curing agent, optionally a curing accelerator, and optionally an inorganic filler into the solution in step (1), homogeneously stirring to obtain a varnish, choosing a reinforcing material having a smooth surface, homogeneously coating the aforesaid varnish, and then baking to obtain a prepreg; and
(3) cutting the prepreg into a suitable size according to the size of the pressing machine, overlaying in order, placing one sheet of copper foil on each side thereof, pressing in a vacuum thermocompressor to obtain a copper clad laminate;

The baking temperature in step (2) was set generally between 85° C. and 175° C. according to the boiling point of the solvent used for the varnish, and the baking generally lasted for 5-20 min.

In step (3), a multistep (heating and increasing the pressure step by step) procedure was used to press, wherein the temperature was increased by 15 min from room temperature to 150° C. and maintained for 30 min, then increased by 5 min to 180° C. and maintained for 2 h, and finally decreased by 30 min to room temperature; the pressure was increased by 1 min from 0 to 0.6 Mpa and maintained for 20 min, and then increased by 1 min to 1.0 Mpa and maintained for 2.5 hours. The post-processing was carried at 200˜245° C. and maintained for 1-5 hours.

As compared with the prior art, the present invention has the following beneficial effects.

The present invention discloses introducing a phenoxycyclotriphosphazene active ester into a thermosetting resin, reacting the active esters with epoxy resin without producing hydroxyl groups, which can not only satisfy the requirements of being halogen-free and flame retardant, but also can improve the electrical properties of the system (i.e., decreasing and stabilizing Dk and Df), so as to make being halogen-free high-frequency and high speed substrate materials possible.

In the present invention, phenoxycyclotriphosphazene active ester is compounded with thermosetting resins such as epoxy resin, benzoxazine resin, cyanate resin, bismaleimide resin, micromolecular polyphenyl ether resin, hydrocarbon resin and the like, cured with a composite curing agent, mixed with some organic and inorganic filler, coated and laminated to obtain a copper clad plate. The resultant copper clad plate meets the requirements on being halogen-free, and has advantages such as excellent heat resistance, humidity resistance and low dielectric loss.

### EXAMPLES

The technical solution of the present invention is further stated by the following examples.

### Example 1

A solvent, a phenoxycyclotriphosphazene containing hydroxyl groups (wherein those containing two hydroxyl groups are in a proportion of higher than 65%), an acid-binding agent and a catalyst were added into a reaction device, stirred, protected by introducing nitrogen, and gradually dripped at a low temperature with a certain amount of p-benzoyl chloride. After reacting for 1-8 hours, a suitable amount of phenol was added, further reacted for 1-8 hours, cooled to room temperature, and filtered by suction. The filtrate was pressure-distilled to evaporate the solvent to obtain a viscous product.

30 g of said product was dissolved in an organic solvent, and then 70 g of DCPD epoxy resin (which is HP-7200H (DIC), and has an equivalent of 275-280) and a suitable amount of imidazole and pyridine were added, homogeneously stirred and mixed to obtain a varnish.

E-glass fabric having a size of 300×300 cm and a smooth and flat surface was homogeneously covered with said varnish, baked in an oven having a temperature of 155° C. for 7 min to obtain a bonding sheet.

Five (5) sheets of bonding sheets above whose edges were removed were superimposed, attached up and down with copper foils having a thickness of 35 μm, placed in a vacuum thermocompressor to press and obtain a copper clad laminate. A multistep procedure (heating and increasing the pressure step by step) was used to press, wherein the temperature was increased by 15 min from room temperature to 150° C. and maintained for 30 min, then increased by 5 min to 180° C. and maintained for 2 hours, and finally decreased by 30 min to room temperature; the pressure was increased by 1 min from 0 to 0.6 Mpa and maintained for 20 min, and then increased by 1 min to 1.0 Mpa and maintained for 2.5 h. The results are shown in Table 1.

### Example 2

A solvent, a phenoxycyclotriphosphazene containing hydroxyl groups (wherein those containing two hydroxyl groups are in a proportion of higher than 65%), an acid-binding agent and a catalyst were added into a reaction device, stirred, protected by introducing nitrogen, and gradually dripped at a low temperature with a certain amount of p-benzoyl chloride. After reacting for 1-8 hours, a suitable amount of phenol was added, further reacted for 1-8 hours, cooled to room temperature, and filtered by suction. The filtrate was pressure-distilled to evaporate the solvent to obtain a viscous product.

30 g of said product was dissolved in an organic solvent, and then 40 g of DCPD benzoxazine (which is LZ8260 (Huntsman)), 20 g of DCPD epoxy resin (which is HP-7200H (DIC), and has an equivalent of 275-280), 10 g of styrene/maleic anhydride (which is EF-30, Sartomer) and a suitable amount of imidazole and pyridine were added, homogeneously stirred and mixed to obtain a varnish.

E-glass fabric having a size of 300×300 cm and a smooth and flat surface was homogeneously covered with said varnish, baked in an oven having a temperature of 155° C. for 7 min to obtain a bonding sheet.

Five (5) sheets of bonding sheets above whose edges were removed were superimposed, attached up and down with copper foils having a thickness of 35 μm, placed in a vacuum thermocompressor to press and obtain a copper clad laminate. A multistep procedure (heating and increasing the pressure step by step) was used to press, wherein the temperature was increased by 15 min from room temperature to 150° C. and maintained for 30 min, then increased by 5 min to 190° C. and maintained for 2 hours, and finally decreased by 30 min to room temperature; the pressure was increased by 1 min from 0 to 0.6 Mpa and maintained for 20 min, and then increased by 1 min to 1.0 Mpa and maintained for 2.5 hours. The results are shown in Table 1.

### Example 3

A solvent, a phenoxycyclotriphosphazene containing hydroxyl groups (wherein those containing two hydroxyl groups are in a proportion of higher than 65%), an acid-binding agent and a catalyst were added into a reaction device, stirred, protected by introducing nitrogen, and gradually dripped at a low temperature with a certain amount of p-benzoyl chloride. After reacting for 1-8 hours, a suitable amount of phenol was added, further reacted for 1-8 hours, cooled to room temperature, and filtered by suction. The filtrate was pressure-distilled to evaporate the solvent to obtain a viscous product.

30 g of said product was dissolved in an organic solvent, and then 30 g of DCPD cyanate (which is LONZA-Primaset DT-4000), 20 g of 4,4′-diphenylmethane bismaleimide, 20 g of DCPD epoxy resin (which is HP-7200H (DIC), and has an equivalent of 275-280), and a suitable amount of aluminium acetylacetonate and pyridine were added, homogeneously stirred and mixed to obtain a varnish.

E-glass fabric having a size of 300×300 cm and a smooth and flat surface was homogeneously covered with said varnish, baked in an oven having a temperature of 155° C. for 7 min to obtain a bonding sheet.

Five (5) sheets of bonding sheets above whose edges were removed were superimposed, attached up and down with copper foils having a thickness of 35 μm, placed in a vacuum thermocompressor to press and obtain a copper clad laminate. A multistep procedure (heating and increasing the pressure step by step) was used to press, wherein the temperature was increased by 15 min from room temperature to 150° C. and maintained for 30 min, then increased by 5 min to 210° C. and maintained for 2 hours, and finally decreased by 30 min to room temperature; the pressure was increased by 1 min from 0 to 0.6 Mpa and maintained for 20 min, and then increased by 1 min to 1.0 Mpa and maintained for 2.5 hours. The results are shown in Table 1.

### Example 4

A solvent, a phenoxycyclotriphosphazene containing hydroxyl groups (wherein those containing two hydroxyl groups are in a proportion of higher than 65%), an acid-binding agent and a catalyst were added into a reaction device, stirred, protected by introducing nitrogen, and gradually dripped at a low temperature with a certain amount of p-benzoyl chloride. After reacting for 1-8 hours, a suitable amount of phenol was added, further reacted for 1-8 hours, cooled to room temperature, and filtered by suction. The filtrate was pressure-distilled to evaporate the solvent to obtain a viscous product.

30 g of said product was dissolved in an organic solvent, and then 50 g of reactive polyphenyl ether resin (which is MX9000, SABIC), 20 g of DCPD epoxy resin (which is HP-7200H (DIC), and has an equivalent of 275-280), and a suitable amount of 2,5-di(2-ethylhexanoylperoxy)-2,5-dimethylhexane and pyridine were added, homogeneously stirred, and mixed to obtain a varnish.

E-glass fabric having a size of 300×300 cm and a smooth and flat surface was homogeneously covered with said varnish, baked in an oven having a temperature of 155° C. for 7 min to obtain a bonding sheet.

Five (5) sheets of bonding sheets above whose edges were removed were superimposed, attached up and down with copper foils having a thickness of 35 μm, placed in a vacuum thermocompressor to press and obtain a copper clad laminate. A multistep procedure (heating and increasing the pressure step by step) was used to press, wherein the temperature was increased by 15 min from room temperature to 150° C. and maintained for 30 min, then increased by 5 min to 190° C. and maintained for 2 hours, and finally decreased by 30 min to room temperature; the pressure was increased by 1 min from 0 to 0.6 Mpa and maintained for 20 min, and then increased by 1 min to 1.0 Mpa and maintained for 2.5 hours. The results are shown in Table 1.

### Example 5

Bisphenol A novolac epoxy resin (BNE200, Taiwan's Chang Chun Plastics Plant) was used to replace DCPD epoxy resin, and the others were the same as those in Example 1.

### Example 6

A solvent, a phenoxycyclotriphosphazene containing hydroxyl groups (wherein those containing two hydroxyl groups are in a proportion of higher than 65%), an acid-binding agent and a catalyst were added into a reaction device, stirred, protected by introducing nitrogen, and gradually dripped at a low temperature with a certain amount of p-benzoyl chloride. After reacting for 1-8 hours, a suitable amount of phenol was added, further reacted for 1-8 hours, cooled to room temperature, and filtered by suction. The filtrate was pressure-distilled to evaporate the solvent to obtain a viscous product.

10 g of said product was dissolved in an organic solvent, and then 15 g of cyanate (which is LONZA-Primaset BA-230s), 5 g of naphthol epoxy resin (which is HPC-9500 (DIC)), and a suitable amount of aluminum acetylacetonate and pyridine were added, homogeneously stirred and mixed to obtain a varnish.

E-glass fabric having a size of 300×300 cm and a smooth and flat surface was homogeneously covered with said varnish, baked in an oven having a temperature of 155° C. for 7 min to obtain a bonding sheet.

Two (2) sheets of bonding sheets above whose edges were removed were superimposed, attached up and down with copper foils having a thickness of 35 μm, placed in a vacuum thermocompressor to press and obtain a copper clad laminate. A multistep (heating and increasing the pressure step by step) procedure was used to press, wherein the temperature was increased by 15 min from room temperature to 150° C. and maintained for 30 min, then increased by 5 min to 210° C. and maintained for 2 hours, and finally decreased by 30 min to room temperature; the pressure was increased by 1 min from 0 to 0.6 Mpa and maintained for 20 min, and then increased by 1 min to 1.0 Mpa and maintained for 2.5 hours. The results are shown in Table 1.

### Example 7

A solvent, a phenoxycyclotriphosphazene containing hydroxyl groups (wherein those containing two hydroxyl groups are in a proportion of higher than 65%), an acid-binding agent and a catalyst were added into a reaction device, stirred, protected by introducing nitrogen, and gradually dripped at a low temperature with a certain amount of p-benzoyl chloride. After reacting for 1-8 hours, a suitable amount of phenol was added, further reacted for 1-8 hours, cooled to room temperature, and filtered by suction. The filtrate was pressure-distilled to evaporate the solvent to obtain a viscous product.

50 g of said product was dissolved in an organic solvent, and then 85 g of DCPD epoxy resin (which is HP-7200H (DIC), and has an equivalent of 275-280), and a suitable amount of imidazole and pyridine were added, homogeneously stirred and mixed to obtain a varnish.

E-glass fabric having a size of 300×300 cm and a smooth and flat surface was homogeneously covered with said varnish, baked in an oven having a temperature of 155° C. for 7 min to obtain a bonding sheet.

1 sheet of bonding sheet above whose edge was removed was superimposed, attached up and down with copper foils having a thickness of 18 μm, placed in a vacuum thermocompressor to press and obtain a copper clad laminate. A multistep (heating and increasing the pressure step by step) procedure was used to press, wherein the temperature was increased by 15 min from room temperature to 150° C. and maintained for 30 min, then increased by 5 min to 180° C. and maintained for 2 hours, and finally decreased by 30 min to room temperature; the pressure was increased by 1 min from 0 to 0.6 Mpa and maintained for 20 min, and then increased by 1 min to 1.0 Mpa and maintained for 2.5 hours. The results are shown in Table 1.

### Comparison Example 1

Except that 30 g of phenoxycyclotriphosphazene in Example 3 was replaced with 30 g of phosphorous-containing phenolic aldehyde (which is Dow Chemical XZ92741), the others were unchanged.

### Comparison Example 2

Except that 30 g of phenoxycyclotriphosphazene in Example 4 was replaced with 30 g of phosphorous-containing phenolic aldehyde (which is Dow Chemical XZ92741), the others were unchanged.

### Comparison Example 3

Except that 30 g of phenoxycyclotriphosphazene in Example 1 was replaced with 30 g of active ester (which is HP8000 by DIC), the others were unchanged.

### Comparison Example 4

Except that 30 g of phenoxycyclotriphosphazene in Example 2 was replaced with 30 g of phosphazo active ester having the following structural formula:

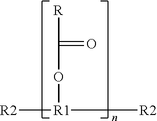

wherein R is phenyl; R1 is phosphazo skeleton; R2 is phenyl,
the others were unchanged.

The results are shown in Table 1.

TABLE 1
Property evaluation

| | | | | | | | | Com. | Com. | Com. | Com. |
|---|---|---|---|---|---|---|---|---|---|---|---|
| | Exp. 1 | Exp. 2 | Exp. 3 | Exp. 4 | Exp. 5 | Exp. 6 | Exp. 7 | Exp. 1 | Exp. 2 | Exp. 3 | Exp. 4 |
| Glass transition | 170~180 | 180~195 | 195~225 | 185~215 | 195~225 | 195~230 | 160~170 | 200~230 | 190~220 | 180~190 | 190~200 |
| temperature | | | | | | | | | | | |
| (Tg, ° C., | | | | | | | | | | | |
| DMA) | | | | | | | | | | | |
| Peeling strength | >1.2 | >1.2 | >0.8 | >0.8 | >1.2 | >1.0 | >1.2 | >1.0 | >1.0 | >1.0 | >1.0 |
| (½ OZ, N/mm) | | | | | | | | | | | |
| Flame- | V-1 | V-0 | V-0 | V-0 | V-1 | V-0 | V-0 | V-0 | V-0 | com- | V-1 |
| retardancy | | | | | | | | | | busting | |
| (1.60 mm) | | | | | | | | | | | |
| Dip soldering | ◯ | Δ | ◯ | ◯ | ◯ | ◯ | ◯ | ◯ | ◯ | ◯ | X |
| resistance | | | | | | | | | | | |
| (delamination) | | | | | | | | | | | |
| Hydroscopicity | 0.07 | 0.06 | 0.08 | 0.07 | 0.010 | 0.006 | 0.008 | 0.12 | 0.12 | 0.06 | 0.15 |
| (%) | | | | | | | | | | | |
| Dielectric | 4.0 | 4.2 | 3.8 | 3.6 | 4.3 | 3.9 | 4.1 | 3.7 | 3.5 | 3.9 | 4.0 |
| constant | | | | | | | | | | | |
| (RC50, 1 GHZ) | | | | | | | | | | | |
| Dielectric loss | 0.010 | 0.009 | 0.005 | 0.003 | 0.018 | 0.004 | 0.011 | 0.005 | 0.003 | 0.009 | 0.010 |
| (RC50, 1 GHZ) | | | | | | | | | | | |
| T-300/min | >60 | >60 | >120 | >120 | >60 | >120 | >60 | >120 | >120 | >120 | >30 |
| Punchability | ◯ | Δ | ◯ | ◯ | ◯ | ◯ | ◯ | Δ | ◯ | ◯ | ◯ |

The aforesaid properties were verified by the following tests.

Flame-retardancy (flame retardancy): tested according to UL 94.

Dip soldering resistance: a sample (a substrate of 100×100 mm) which was maintained for 2 hours in a pressure cooking processing device at 121° C. and 105 KPa was dipped for 20 seconds in a solder bath heated to 260° C., to visually observe (h1) whether there was delamination, and (h2) whether there were white spots or wrinkles. The symbols ◯ represents unchanged; Δ represents that there are white spots.

Hydroscopicity: tested according to IPC-TM-650 2.6.2.1.

Dielectric dissipation factor: tested under 1 GHz according to IPC-TM-650 2.5.5.5 and the resonance method of strips.

Punchability: a substrate having a thickness of 1.60 mm was placed on a die having a certain patterning for punching, to visually observe (h1) whether there were no white circles on the side of holes, (h2) whether there were white circles on the side of holes, and (h3) there were crackings on the side of holes, represented by the symbols ◯, Δ and X.

It can be seen according to the results above that phenoxycyclotriphosphazene active esters contain N and P atoms and have a better flame retardant effect as compared with HP8000 active esters by DIC, and has a low water absorption as compared with the active esters containing phosphates in Comparison Example 4. Phenoxycyclotriphosphazene active esters of the present invention can realize halogen-free flame retardancy without decreasing the dielectric properties (the halogen content falls within the scope of JPCA halogen-free standard), and have excellent heat resistance and better processibility.

The applicant declares that, the present invention detailedly discloses the process of the present invention by the aforesaid examples, but the present invention is not limited by the detailed process, i.e., it does not mean that the present invention cannot be fulfilled unless the aforesaid detailed process is used. Those skilled in the art shall know that, any amendment, equivalent change to the product materials of the present invention, addition of auxiliary ingredients, and selection of any specific modes all fall within the protection scope and disclosure scope of the present invention.

1. A phenoxycyclotriphosphazene active ester comprising at least 65 mol. % of a substance having the following structural formula: 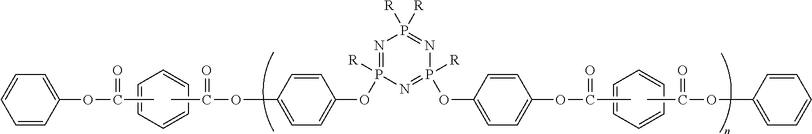
wherein, 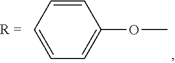
and n represents any number between 0.25 and 3.

2. A halogen-free resin composition wherein the halogen-free resin composition comprises about 5 to about 50 parts by weight of the phenoxycyclotriphosphazene active ester in claim 1, about 15 to about 85 parts by weight of a thermosetting resin, about 1 to about 35 parts by weight of a curing agent, about 0 to about 5 parts by weight of a curing accelerator and about 0 to about 100 parts by weight of an inorganic filler,
wherein the thermosetting resin is anyone selected from the group consisting of epoxy resin, benzoxazine resin, cyanate resin, bismaleimide resin, reactive polyphenyl ether resin or hydrocarbon resin, or a mixture of at least two selected therefrom.

3. The halogen-free resin composition of claim 2, wherein the thermosetting resin comprises dicyclopentadiene, biphenyl or naphthalene ring group.

4. The halogen-free resin composition of claim 2, characterized in that the epoxy resin is anyone selected from the group consisting of bisphenol A epoxy resin, bisphenol F epoxy resin, DCPD epoxy resin, triphenol epoxy resin, biphenyl epoxy resin or naphthol epoxy resin, or a mixture of at least two or more thereof.

5. The halogen-free resin composition of claim 2, wherein the epoxy resin is a phosphorous-containing epoxy resin containing about 1.5 to about 6.0 wt. % of phosphorous.

6. The halogen-free resin composition of claim 2, wherein the benzoxazine resin is selected from the group consisting of bisphenol A benzoxazine resin, bisphenol F benzoxazine resin, DCPD benzoxazine resin or phenothalin benzoxazine resin, or a mixture of at least two or more thereof.

7. The halogen-free resin composition of claim 2, wherein the cyanate resin is selected from the group consisting of bisphenol A cyanate resin, DCPD cyanate resin or phenolic aldehyde cyanate resin, or a mixture of at least two or more thereof.

8. The halogen-free resin composition of claim 2, wherein the bismaleimide resin comprises 4,4′-diphenylmethane bismaleimide, allyl-modified diphenylmethane bismaleimide, or a combination of two or more thereof.

9. The halogen-free resin composition of claim 2, wherein the reactive polyphenyl ether resin has an average molecular weight of about 1000 to about 7000, and has reactive groups of hydroxyl groups, double bonds, or both.

10. The halogen-free resin composition of claim 2, wherein the hydrocarbon resin is selected from the group consisting of vinyl styrene butadiene resin having a average molecular weight of about less than 11,000, vinyl polybutadiene resin having polar groups or maleic anhydride-grafted butadiene and styrene resin, or a copolymer of at least two or more thereof.

11. The halogen-free resin composition of claim 2, wherein the curing agent is selected from the group consisting of dicyandiamide, aromatic amine, anhydride, phenolic compounds, triene isocyanurate or phosphorous-containing phenolic aldehyde, or a mixture of at least two or more thereof.

12. The halogen-free resin composition of claim 2, wherein the curing accelerator is selected from the group consisting of 2-methylimidazole, 2-ethyl-4-methylimidazole, 2-phenylimidazole, pyridine, DMP-30, hexamethylenetetramine, dicumyl peroxide, t-butyl peroxybenzoate, 2,5-di(2-ethylhexanoylperoxy)-2,5-dimethylhexane, acetylacetonate or zincate, or a mixture of at least two or more thereof.

13. The halogen-free resin composition of claim 2, wherein the inorganic filler is selected from the group consisting of aluminum hydroxide, magnesium hydroxide, zeolite, wollastonite, silica, magnesium oxide, calcium silicate, calcium carbonate, clay, talc or mica, or a mixture of at least two or more thereof.

14. The halogen-free resin composition of claim 2, wherein the inorganic filler is in an amount of 25 to 100 parts by weight.

15. A prepreg, wherein the prepreg comprises a reinforcing material and the halogen-free resin composition of claim 2 and attached thereon after impregnation and drying.

16. A laminate, wherein the laminate comprises at least one prepreg of claim 15.

17. A printed wiring board, wherein the printed wiring board comprises at least one prepreg of claim 15.
